(19) United States
(12) Patent Application Publication
(10) Pub. No.: US 2024/0413013 A1
(43) Pub. Date: Dec. 12, 2024

(54) MANUFACTURING METHOD FOR ELEMENT CHIP AND MANUFACTURING METHOD FOR BONDED BODY

(71) Applicant: Panasonic Intellectual Property Management Co., Ltd., Osaka (JP)

(72) Inventor: Shogo OKITA, HYOGO (JP)

(21) Appl. No.: 18/588,505

(22) Filed: Feb. 27, 2024

(30) Foreign Application Priority Data
Jun. 12, 2023 (JP) 2023-096289

(51) Int. Cl. H01L 21/78; H01L 23/00

(52) U.S. Cl. CPC H01L 21/78; H01L 24/80; H01L 2224/80895; H01L 2224/80896

(57) ABSTRACT

The method includes a process of preparing a substrate 1 that includes a first layer 2 and a second layer 3 and includes a division region, a process of flattening an upper surface of the layer 3, a process of forming a protective layer 4 on the flattened upper surface to form a boundary 6 between the layer 3 and the layer 4, a process of removing the layers 3, 4 in the division region using laser light to form a groove 5 reaching the layer 2, and depositing, on side walls of the groove 5, a deposit D so as to cover the boundary 6, a process of removing the deposit D to expose the boundary 6 on the side walls, and a process of etching the layer 2 by exposing the groove 5 to plasma, and thereby dividing the substrate 1 into a plurality of element chips.

### CROSS REFERENCE TO RELATED APPLICATION

The present application is based on and claims priority under 35 U.S.C. § 119 with respect to the Japanese Patent Application No. 2023-096289 filed on Jun. 12, 2023, of which entire content is incorporated herein by reference into the present application.

### TECHNICAL FIELD

The present disclosure relates to a manufacturing method for an element chip and a manufacturing method for a bonded body.

### BACKGROUND

There have been conventionally known techniques for manufacturing a plurality of element chips by subjecting a substrate to plasma dicing (for example, JP 2005-191039A). The manufacturing method for an element chip described in JP 2005-191039A includes a process of preparing a substrate that includes a plurality of element regions and a division region defining the element regions, a process of forming a mask layer on the upper surface of the substrate, a process of removing the mask layer corresponding to the division region by irradiation with laser light, and a process of obtaining a plurality of element chips corresponding to the element regions by exposing the division region of the substrate to plasma.

### SUMMARY

In recent years, the development of a so-called hybrid bonding technique for directly bonding the surfaces of element chips or the surfaces of an element chip and a substrate has been underway. The hybrid bonding technique is advantageous in that the bond distance can be shortened, but requires that the surfaces of element chips or the like are highly flat. Under such circumferences, one object of the present disclosure is to obtain an element chip with a flat surface.

An aspect of the present disclosure relates to a manufacturing method for an element chip. The manufacturing method includes: a preparation process of preparing a substrate that includes a first principal surface and a second principal surface and includes a first layer that is a semiconductor layer and a second layer that is formed on the first principal surface side of the first layer and contains an insulator, the substrate including a plurality of element regions and a division region defining the element regions; a flattening process of flattening an upper surface of the second layer by polishing the first principal surface side of the substrate; a protective layer formation process of forming a protective layer on the flattened upper surface to form a boundary between the second layer and the protective layer; a laser grooving process of irradiating the division region with laser light from the first principal surface side and removing the protective layer and the second layer in the division region to form a groove in the division region that penetrates through the protective layer and the second layer and reaches the first layer, and depositing, on side walls of the groove, a deposit containing compositions of the protective layer and the second layer removed by the irradiation with the laser light so as to cover at least the boundary; a deposit removal process of removing the deposit to expose the boundary on the side walls; and a plasma dicing process of, after the deposit removal process, etching the first layer by exposing the groove to plasma in a state where the second principal surface is supported by a support member, and thereby dividing the substrate into a plurality of element chips including the element regions.

Another aspect of the present disclosure relates to a manufacturing method for a bonded body. The manufacturing method includes: an element chip preparation process of preparing an element chip; a second substrate preparation process of preparing a second substrate; and a bonding process of bonding the element chip to the second substrate. The element chip preparation process includes: a preparation process of preparing a first substrate that includes a first principal surface and a second principal surface and includes a first layer that is a semiconductor layer and a second layer that is formed on the first principal surface side of the first layer and contains an insulator, the first substrate including a plurality of element regions and a division region defining the element regions; a flattening process of flattening an upper surface of the second layer by polishing the first principal surface side of the first substrate; a protective layer formation process of forming a protective layer on the flattened upper surface to form a boundary between the second layer and the protective layer; a laser grooving process of irradiating the division region with laser light from the first principal surface side and removing the protective layer and the second layer in the division region to form a groove in the division region that penetrates through the protective layer and the second layer and reaches the first layer, and depositing, on side walls of the groove, a deposit containing compositions of the protective layer and the second layer removed by the irradiation with the laser light so as to cover at least the boundary; a deposit removal process of removing the deposit to expose the boundary on the side walls; a plasma dicing process of, after the deposit removal process, etching the first layer by exposing the groove to plasma in a state where the second principal surface is supported by a support member, and thereby dividing the first substrate into a plurality of the element chips including the element regions; and a protective layer removal process of, after the plasma dicing process, removing the protective layer. In the bonding process, the first principal surface side of the element chip is brought into areal contact with and bonded to the second substrate.

According to the present disclosure, it is possible to obtain an element chip with a flat surface.

### BRIEF DESCRIPTION OF THE DRAWINGS

FIG. 1 is a cross-sectional diagram for describing a preparation process, illustrating an example of a first substrate.

FIG. 2 is a cross-sectional diagram for describing a flattening process in which a first principal surface of the first substrate is flattened.

FIG. 3 is a cross-sectional diagram for describing a protective layer formation process in which a protective layer is formed on the upper surface of a second layer.

FIG. 4 is a cross-sectional diagram for describing a laser grooving process in which a groove is formed and a deposit is deposited on the side surfaces of the groove.

FIG. 5 is a cross-sectional diagram for describing a first removal step of a deposit removal process in which mainly the deposit on the bottom surface of the groove is removed.

FIG. 6 is a cross-sectional diagram for describing a second removal step of the deposit removal process in which mainly the deposit around a boundary is removed.

FIG. 7 is a cross-sectional diagram for describing a plasma dicing process, illustrating a plurality of element chips.

FIG. 8 is a cross-sectional diagram for describing a protective layer removal process in which the protective layer is removed.

FIG. 9 is a cross-sectional diagram for describing a second substrate preparation process and a bonding process, illustrating a state where an element chip is being bonded to a second substrate.

FIG. 10 is a schematic diagram illustrating an example of a plasma treatment apparatus.

### DETAILED DESCRIPTION

Embodiments of a manufacturing method for an element chip and a manufacturing method for a bonded body according to the present disclosure will be described below by way of examples. However, the present disclosure is not limited to the examples described below. In the following description, specific numerical values and materials will be illustrated. However, other numerical values and materials may also be applied as long as the advantageous effects of the present disclosure can be obtained.

### Manufacturing Method for Element Chip

A manufacturing method for an element chip according to the present disclosure is a method for obtaining a plurality of element chips by dividing a substrate into pieces. The manufacturing method for an element chip according to the present disclosure includes a preparation process, a flattening process, a protective layer formation process, a laser grooving process, a deposit removal process, and a plasma dicing process.

In the preparation process, a substrate is prepared that includes a first principal surface and a second principal surface and includes a first layer that is a semiconductor layer and a second layer that is formed on the first principal surface side of the first layer and contains an insulator. The substrate includes a plurality of element regions and a division region that defines the element regions. The first layer and the second layer may be adjacent to each other. A semiconductor material contained in the first layer is not limited in particular, and may be Si, SiC, GaN, or GaAs, for example. The second layer may contain an insulation film of SiO₂, SiN, SiCN, or the like, and a metal such as Cu or Al, for example. The shape of each element region is not limited in particular and may be rectangular, polygonal, or circular, for example. The width of the division region is not limited in particular and can be set as appropriate according to the purpose.

In the flattening process, the first principal surface side of the substrate is polished to flatten the upper surface of the second layer. In the flattening process, the upper surface of the second layer may be flattened by chemical mechanical polishing (CMP), for example. The upper surface (or the topmost surface) of the second layer may contain SiO₂ or SiON.

In the protective layer formation process, a protective layer is formed on the flattened upper surface of the second layer to form a boundary between the second layer and the protective layer. The protective layer may contain a water-soluble or water-insoluble resin material. The thickness of the protective layer is not limited in particular and need only be large enough not to be fully removed in the plasma dicing process. An example of the water-insoluble resin material is a photoresist material.

In the laser grooving process, the division region is irradiated with laser light from the first principal surface side to remove the protective layer and the second layer in the division region. As a result, a groove is formed in the division region that penetrates through the protective layer and the second layer and reaches the first layer, and a deposit (or debris) containing compositions of the protective layer and the second layer removed by the irradiation with the laser light is deposited on the side walls of the groove so as to cover at least the boundary. The laser light may be ultrashort pulse laser light on the order of picoseconds or femtoseconds. However, from the viewpoint of manufacturing cost, the laser light is preferably short-pulse laser light on the order of nanoseconds. The laser light is absorbed by the protective layer and the second layer but need not be absorbed by the first layer.

As a result of intensive studies, it was found that the deposit covering the boundary between the second layer and the protective layer and its vicinity contributed to the formation of minute projections (or burrs) on the surface of the element chip obtained later. Such minute projections frequently have sizes of several tens to several hundreds of nanometers, which may impede interface bonding in the hybrid bonding.

To prevent this, in the deposit removal process, the deposit is removed to expose the boundary on the side walls of the groove. The deposit may be removed by plasma treatment. In this manner, removing the deposit from the boundary between the second layer and the protective layer and its vicinity suppresses the formation of minute projections on the surface of the element chip obtained later.

In the plasma dicing process, after the deposit removal process, the first layer is etched by exposing the groove to plasma in a state where the second principal surface is supported by a support member, whereby the substrate is divided into a plurality of element chips including the element regions. The plasma etching can be performed with the protective layer serving as a mask. The first layer may be etched using the Bosch process. The support member may have an annular frame and a holding sheet that is attached to the frame and to which the substrate is to be adhered. The element chip obtained later has few minute projections on its surface as described above. Even if the element chip has minute projections on the surface, the sizes of the minute projections are several nanometers or less, which is unlikely to impede the interface bonding in the hybrid bonding.

The deposit removal process may be performed by placing the substrate on a stage of a plasma treatment apparatus to which radio-frequency power can be applied and exposing the substrate to plasma. The deposit removal process may include a first removal step that is performed in a state where first radio-frequency power is applied to the stage, and a second removal step that is performed after the first removal step in a state where second radio-frequency power is applied to the stage. The second radio-frequency power may be larger than the first radio-frequency power. For example, the first radio-frequency power may be 20 W or more and 100 W or less, and the second radio-frequency power may be 150 W or more and 600 W or less.

The first removal step may be performed by first plasma that is generated with supply of a first raw material gas containing a fluorocarbon and oxygen. The second removal step may be performed by second plasma that is generated with supply of a second raw material gas containing a fluorocarbon, oxygen, and a rare gas. The proportion of the rare gas contained in the second raw material gas may be higher than the proportion of the rare gas contained in the first raw material gas. The first raw material gas need not contain the rare gas. The second removal step is performed by the second plasma that is generated with supply of the second raw material gas containing a relatively large amount of the rare gas in a state where the relatively large second radio-frequency power is applied to the stage. Thus, the deposit on the side walls of the groove is effectively removed by the effect of sputtering, and thus the boundary between the second layer and the protective layer can be easily exposed.

The deposit removal process may be performed by plasma that is capable of etching the protective layer and the second layer. The plasma that is capable of etching the protective layer and the second layer can be plasma that is generated with supply of a raw material gas containing a fluorocarbon, oxygen, and a rare gas, for example. The raw material gas may further contain SF₆. Through the deposit removal process, the width of the groove at the boundary between the second layer and the protective layer may be increased. The width of the groove at the boundary refers to the width of the groove at the position of the boundary in the depth direction of the groove. The width of the groove may be increased by 50 nm or more and 2000 nm or less in the deposit removal process.

The groove formed in the laser grooving process may have an inclined shape so as to become narrower toward the bottom surface. Through the deposit removal process, the inclination angle of the side surfaces of the groove in the boundary between the second layer and the protective layer may become smaller. The inclination angle of the side surfaces of the groove in the boundary refers to the acute angle formed by the tangent to each side surface of the groove in the boundary and the flat plane on which the boundary exists. The inclination angle may be 65° or more and 90° or less before the deposit removal process, and may be 60° or more and 88° or less after the deposit removal process.

The protective layer may contain a water-soluble resin. In this case, it is possible to reduce the environmental load in the manufacture of the element chip. Examples of the water-soluble resin include polyvinyl acetate or saponified products thereof (partially saponified polyvinyl acetate, polyvinyl alcohol, and the like), polyacrylic acid, polymethacrylic acid, polyacrylamide, 2-acrylamide-2-methylpropanesulfonic acid, polyvinylpyrrolidone, polystyrene sulfonic acid, polyethylene oxide, water-soluble polyester, oxazole-based water-soluble polymers (oxazole-2-etyl-4,5-dihydrohomopolymer and the like), or salts thereof (alkali metallic salt, ammonium salt, and the like).

The manufacturing method for an element chip may further include a protective layer removal process of, after the plasma dicing process, removing the protective layer by bringing the protective layer into contact with a cleaning solution containing water (for example, water). At the time of removal of the protective layer, if the deposit is left at the boundary between the second layer and the protective layer, the minute projections of several tens to several hundreds of nanometers described above can be formed on the surface of the element chip. However, since the manufacturing method for an element chip according to the present disclosure includes the deposit removal process described above, such minute projections are hardly formed, or even if they are formed, their sizes can be kept to several nanometers.

### Manufacturing Method for Bonded Body

The manufacturing method for a bonded body according to the present disclosure is a method for manufacturing a bonded body by bonding an element chip obtained by dividing a substrate into pieces by plasma etching, to a second substrate. The manufacturing method for a bonded body according to the present disclosure includes an element chip preparation process, a second substrate preparation process, and a bonding process.

The element chip preparation process has, as the manufacturing method for an element chip according to the present disclosure does, a preparation process, a flattening process, a protective layer formation process, a laser grooving process, a deposit removal process, and a plasma dicing process, and further has a protective layer removal process. The processes other than the protective layer removal process may be performed in the same manner as the processes in the manufacturing method for an element chip according to the present disclosure in which the “substrate” is replaced with a “first substrate”. In the protective layer removal process, after the plasma dicing process, the protective layer is removed. At that time, the deposit removal process can suppress the formation of minute projections of several tens to several hundreds of nanometers on the surface of the element chip. The surface of the element chip may be subjected to hydrophilization treatment using plasma.

In the second substrate preparation process, a second substrate is prepared. The surface of the second substrate may include an area made of SiO₂ or SiON and an area made of a metal such as Cu or Al. The surface of the second substrate may be subjected to hydrophilization treatment using plasma.

In the bonding process, the element chip is bonded to the second substrate. In the bonding process, the first principal surface side of the element chip is brought into areal contact with and bonded to the second substrate. The bonding process may be performed by hybrid bonding. Since there are no minute projections of several tens to several hundreds of nanometers on the surface of the element chip, the bonding can be favorably performed.

The deposit removal process is performed by placing the substrate on a stage of a plasma treatment apparatus to which radio-frequency power can be applied and exposing the substrate to plasma. The deposit removal process may include a first removal step that is performed in a state where first radio-frequency power is applied to the stage, and a second removal step that is performed after the first removal step in a state where second radio-frequency power is applied to the stage.

The first removal step may be performed by first plasma that is generated with supply of a first raw material gas containing a fluorocarbon and oxygen. The second removal step may be performed by second plasma that is generated with supply of a second raw material gas containing a fluorocarbon, oxygen, and a rare gas. The proportion of the rare gas contained in the second raw material gas may be higher than the proportion of the rare gas contained in the first raw material gas.

The deposit removal process may be performed by plasma that is capable of etching the protective layer and the second layer. The plasma that is capable of etching the protective layer and the second layer can be plasma that is generated with supply of a raw material gas containing a fluorocarbon, oxygen, and a rare gas, for example. The raw material gas may further contain SF₆. Through the deposit removal process, the width of the groove at the boundary between the second layer and the protective layer may be increased.

The groove formed in the laser grooving process may have an inclined shape so as to become narrower toward the bottom surface. Through the deposit removal process, the inclination angle of the side surfaces of the groove in the boundary between the second layer and the protective layer may become smaller.

The protective layer may contain a water-soluble resin. Examples of the water-soluble resin include polyvinyl acetate or saponified products thereof (partially saponified polyvinyl acetate, polyvinyl alcohol, and the like), polyacrylic acid, polymethacrylic acid, polyacrylamide, 2-acrylamide-2-methylpropanesulfonic acid, polyvinylpyrrolidone, polystyrene sulfonic acid, polyethylene oxide, water-soluble polyester, oxazole-based water-soluble polymers (oxazole-2-etyl-4,5-dihydrohomopolymer and the like), or salts thereof (alkali metallic salt, ammonium salt, and the like).

In the protective layer removal process, the protective layer may be removed by bringing the protective layer into contact with a cleaning solution containing water.

As described above, according to the present disclosure, it is possible to obtain an element chip with a flat surface that is suitable for hybrid bonding. Further, according to the present disclosure, it is possible to manufacture a bonded body including such an element chip by hybrid bonding.

Hereinafter, examples of a manufacturing method for an element chip and a manufacturing method for a bonded body will be specifically described with reference to the drawings. The processes described above can be applied to the processes of the examples of the manufacturing method for an element chip and the manufacturing method for a bonded body. The processes of the examples of the manufacturing method for an element chip and the manufacturing method for a bonded body can be changed based on the above description. In addition, the matter described below may be applied to the above-described embodiment. Among the processes of the examples of the manufacturing method for an element chip and the manufacturing method for a bonded body described below, processes that are not essential to the manufacturing method for an element chip and the manufacturing method for a bonded body according to the present disclosure may be omitted. The drawings referred to below are schematic diagrams and do not accurately reflect the shapes and numbers of the actual members.

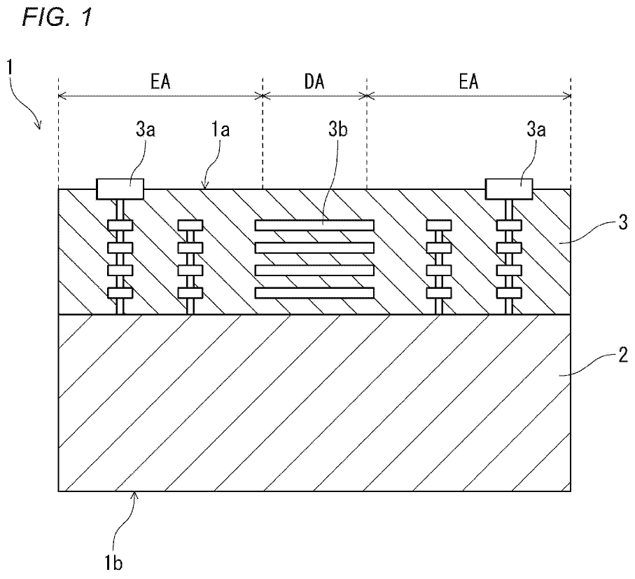

The manufacturing method for a bonded body of the present embodiment is a method for manufacturing a bonded body by bonding an element chip obtained by dividing a substrate into pieces by plasma etching, to a second substrate. The manufacturing method for a bonded body includes an element chip preparation process of preparing an element chip 10, a second substrate preparation process of preparing a second substrate 50, and a bonding process of bonding the element chip 10 to the second substrate 50, as illustrated in FIGS. 1 to 9.

The element chip preparation process is a process that can correspond to the manufacturing method for an element chip according to the present disclosure. The element chip preparation process has a preparation process, a flattening process, a protective layer formation process, a laser grooving process, a deposit removal process, a plasma dicing process, and a protective layer removal process.

In the preparation process, as illustrated in FIG. 1, a first substrate 1 is prepared that includes a first principal surface 1a and a second principal surface 1b and includes a first layer 2 that is a semiconductor layer and a second layer 3 that is formed on the first principal surface 1a side of the first layer 2 and contains an insulator. The first substrate 1 includes a plurality of element regions EA and a division region DA that defines the element regions EA. In the present embodiment, the upper surface (topmost surface) of the second layer 3 contains SiO₂, but the present disclosure is not limited to this. At least one metal electrode 3a is arranged on the second layer 3 corresponding to the element regions EA. At least one metal electrode 3b is arranged on the second layer 3 corresponding to the division region DA. The metal electrode 3a corresponding to the element regions EA partially protrudes from the upper surface of the second layer 3, for example.

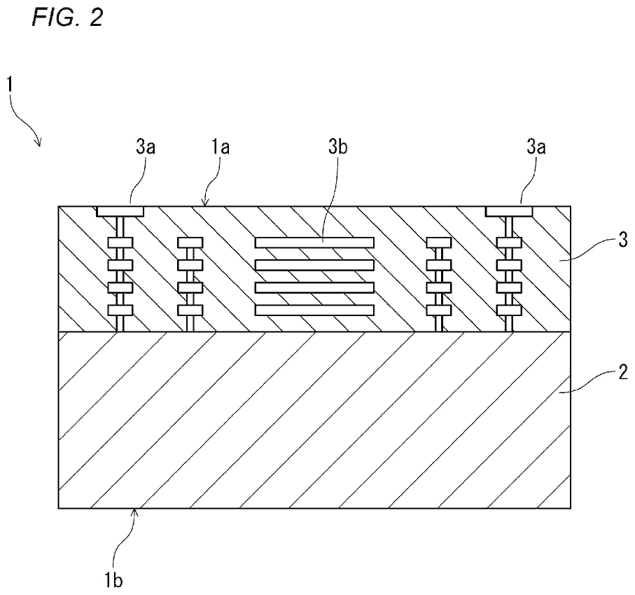

In the flattening process, as illustrated in FIG. 2, the first principal surface 1a side of the first substrate 1 is polished to flatten the upper surface of the second layer 3. In the present embodiment, the upper surface of the second layer 3 is flattened by CMP, but the present disclosure is not limited to this.

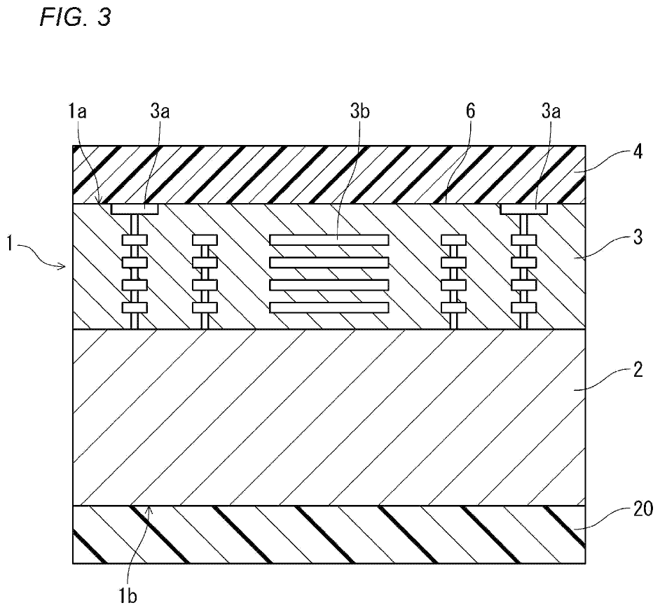

In the protective layer formation process, as illustrated in FIG. 3, a protective layer 4 is formed on the flattened upper surface of the second layer 3 to form a boundary 6 between the second layer 3 and the protective layer 4. The protective layer 4 of the present embodiment contains a water-soluble resin but the present disclosure is not limited to this. The protective layer formation process and the subsequent processes may be performed in a state where the second principal surface 1b of the first substrate 1 is supported by a support member 20 (for example, a holding sheet made of resin).

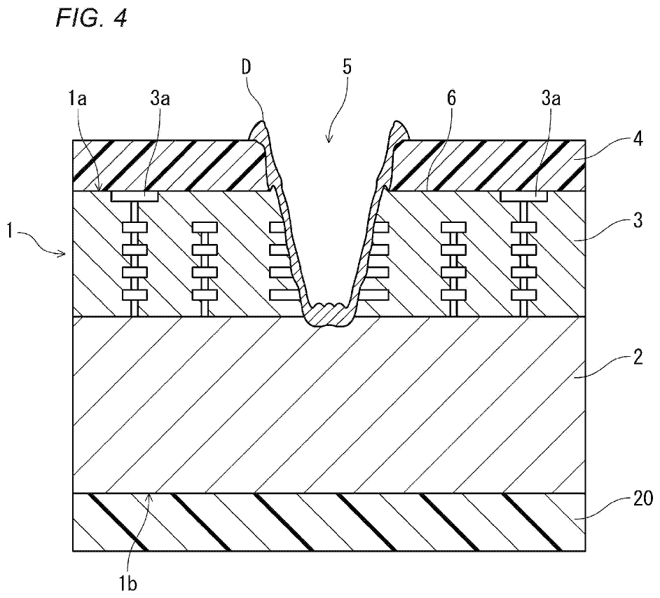

In the laser grooving process, as illustrated in FIG. 4, the division region DA is irradiated with laser light (not illustrated) from the first principal surface 1a side to remove the protective layer 4 and the second layer 3 in the division region DA. As a result, a groove 5 that penetrates through the protective layer 4 and the second layer 3 and reaches the first layer 2 is formed in the division region DA and a deposit D containing compositions of the protective layer 4 and the second layer 3 removed by the irradiation of the laser light is deposited on the side walls of the groove 5 so as to cover at least the boundary 6. In the present embodiment, the deposit D is deposited on substantially the entirety of the side walls of the groove 5. The groove 5 formed in the laser grooving process has a shape that inclines so as to become narrower toward the bottom surface (downward in FIG. 4).

FIG. 4 illustrates minute projections in the vicinity of the boundary 6 for the sake of facilitating understanding of the technical contents of the present disclosure. That is, it is inferred that such minute projections are formed on the surface of the element chip as a result of the removal of the protective layer 4 in the conventional manufacturing method, and are formed from a portion of the residual deposit D deposited around the boundary 6. That is, it is inferred that in the state in FIG. 4, the minute projections constitute a portion of the deposit D and are not so clearly present.

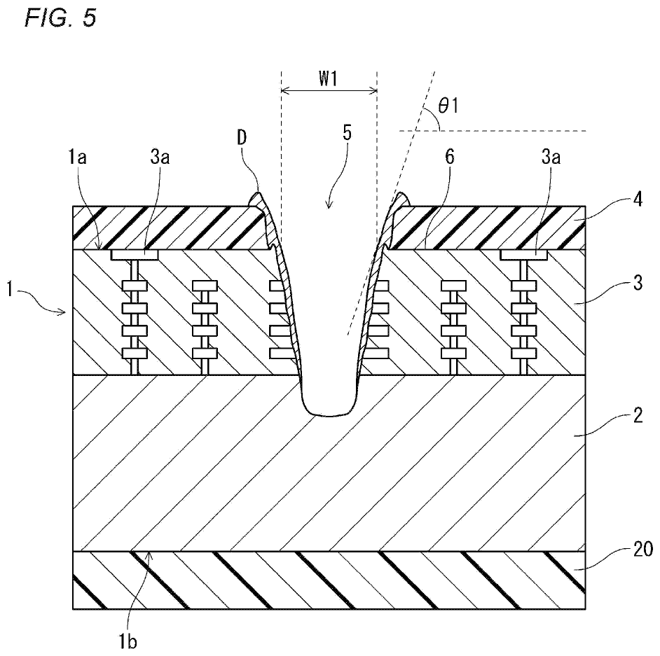

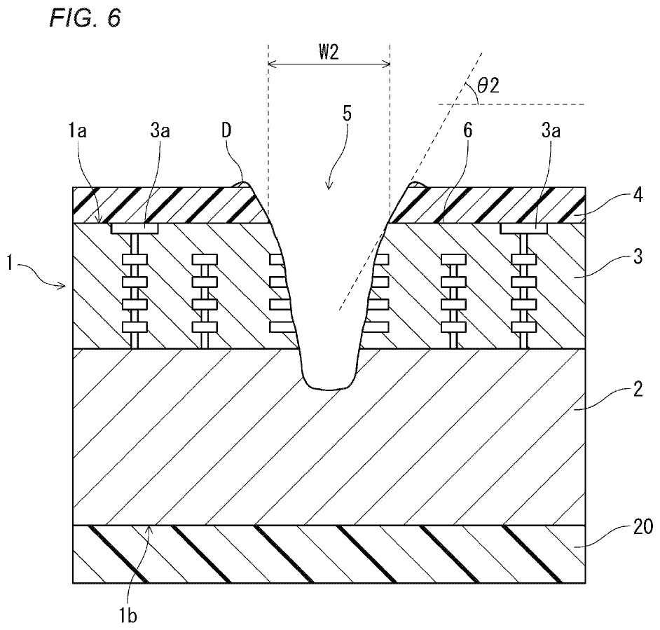

In the deposit removal process, as illustrated in FIGS. 5 and 6, the deposit D is removed to expose the boundary 6 on the side walls of the groove 5. The deposit removal process includes a first removal step (that can correspond to the conventional debris cleaning process) that is performed by placing the first substrate 1 on a stage 35 of a plasma treatment apparatus 30 (described later) to which radio-frequency power is applicable and exposing the first substrate 1 to plasma in a state where first radio-frequency power is applied, and a second removal step that is performed after the first removal step in a state where second radio-frequency power larger than the first radio-frequency power is applied to the stage 35. The first removal step is performed by first plasma that is generated with supply of a first raw material gas containing a fluorocarbon and oxygen. The second removal step is performed by second plasma that is generated with supply of a second raw material gas containing a fluorocarbon, oxygen, and a rare gas (for example, Ar). The proportion of the rare gas contained in the second raw material gas is higher than the proportion of the rare gas contained in the first raw material gas. The second plasma is an example of plasma that is capable of etching the protective layer 4 and the second layer 3. As illustrated in FIGS. 5 and 6, by the deposit removal process, the width of the groove 5 at the boundary 6 is increased (W1<W2), and the inclination angle of the side surfaces of the groove 5 in the boundary 6 becomes smaller (θ1>θ2).

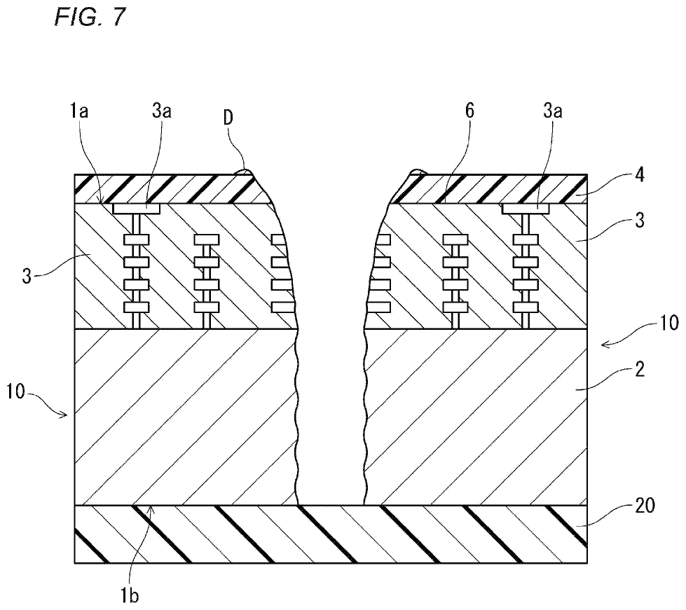

In the plasma dicing process, as illustrated in FIG. 7, after the deposit removal process, the first layer 2 is etched by exposing the groove 5 to plasma in a state where the second principal surface 1b is supported by the support member 20, whereby the first substrate 1 is divided into a plurality of element chips 10 including the element regions EA.

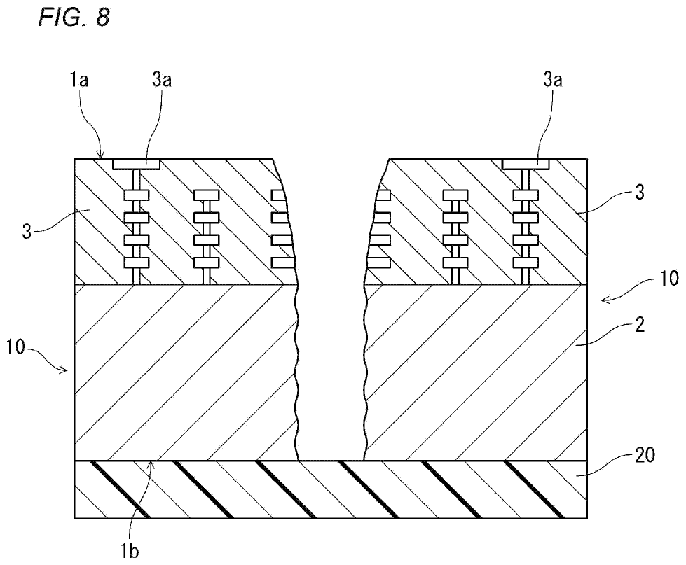

In the protective layer removal process, as illustrated in FIG. 8, after the plasma dicing process, the protective layer 4 is removed. In the protective layer removal process of the present embodiment, the protective layer 4 is removed by bringing the protective layer 4 into contact with a cleaning solution containing water (for example, water), but the present disclosure is not limited to this. In the protective layer removal process, the residual deposit D on the surface of the protective layer 4 can be removed together with the protective layer 4.

The second substrate 50 prepared in the second substrate preparation process may include a semiconductor layer 51 and a wiring layer 52 that is provided on the upper surface of the semiconductor layer 51 and contains an insulator. The insulator (for example, SiO₂) and the metal electrodes 52a are exposed on the topmost surface of the wiring layer 52.

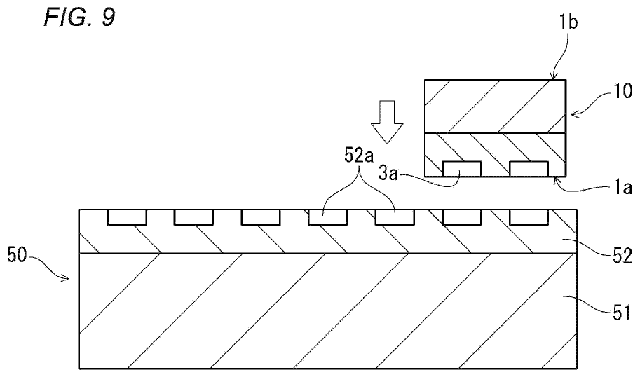

In the bonding process, as illustrated in FIG. 9, the first principal surface 1a side of the element chip 10 prepared in the element chip preparation process is brought into areal contact with and bonded to the second substrate 50 prepared in the second substrate preparation process. At this time, since there are no projections of several tens to several hundreds of nanometers on the first principal surface 1a of the element chip 10, the bonding can be favorably performed. Prior to the bonding process, the first principal surface 1a of the element chip 10 and the surface of the second substrate 50 are preferably subjected to hydrophilization treatment using plasma or the like.

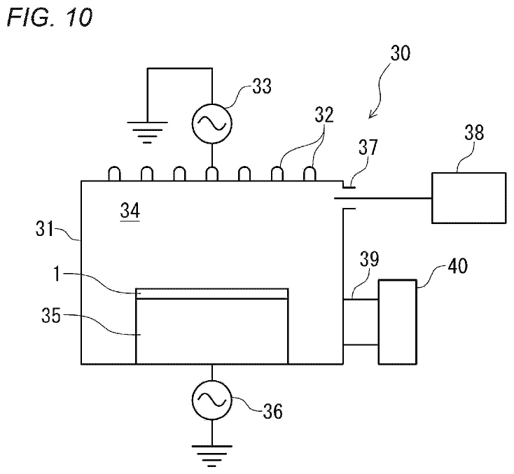

In the deposit removal process and the plasma dicing process, the plasma treatment apparatus 30 (plasma etching apparatus 30) illustrated in FIG. 10 may be used. The plasma treatment apparatus 30 includes a chamber 31 that has a dielectric window atop and defines a treatment room 34, antennas 32 that are upper electrodes provided on the upper side of the chamber 31, a first radio-frequency power source 33 that is electrically connected to the antennas 32, the stage 35 serving as a lower electrode that is provided on the bottom side of the treatment room 34 and on which the first substrate 1 is placed, and a second radio-frequency power source 36 that is electrically connected to the stage 35. A gas inlet 37 provided in the chamber 31 is fluidically connected to a raw material gas source 38. An exhaust outlet 39 provided in the chamber 31 is fluidically connected to a vacuum exhaust part 40 including a vacuum pump.

In the plasma treatment apparatus 30 illustrated in FIG. 10, after the first substrate 1 is placed on the stage 35, the treatment room 34 is subjected to pressure reduction by the vacuum exhaust part 40, and a raw material gas is supplied from the raw material gas source 38 to the treatment room 34. After that, radio-frequency power is supplied from the first radio-frequency power source 33 to the antennas 32 to generate plasma in the treatment room 34, and the plasma is applied to the first substrate 1. The first layer 2 exposed on the bottom part of the groove 5 can be removed by physicochemical effects of radicals and ions in the plasma. The speed of collision of the radicals and ions with the first substrate 1 can be controlled by supplying radio-frequency power from the second radio-frequency power source 36 to the stage 35.

The processing conditions in the deposit removal process are as described below, for example. As process gases, 5 sccm or more and 50 sccm or less of SF₆, 5 sccm or more and 50 sccm or less of C₄F₈, 40 sccm or more and 500 sccm or less of Ar, and 5 sccm or more and 50 sccm or less of O₂ are supplied to the chamber 31. The pressure in the chamber 31 is 1 Pa or more and 5 Pa or less. The radio-frequency power applied to the antennas 32 is 1500 W or more and 5000 W or less. The radio-frequency power applied to the stage 35 is 100 W or more and 1000 W or less. The processing time is 20 seconds or more and 180 seconds or less. Under the processing conditions in this example, as fluorine-containing gases, SF₆ and C₄F₈ are used, but CF₄ may be used instead.

The deposit removal process may include a first removal step and a second removal step. The processing conditions in the first removal step are as described below, for example. As process gases, 50 sccm or more and 200 sccm or less of CF₄, and 50 sccm or more and 200 sccm or less of O₂ are supplied to the chamber 31. The pressure in the chamber 31 is 3 Pa or more and 8 Pa or less. The radio-frequency power supplied to the antennas 32 is 1500 W or more and 5000 W or less. The radio-frequency power applied to the stage 35 is 20 W or more and 100 W or less. The processing time is 30 seconds or more and 120 seconds or less. The processing conditions in the second removal step are as described below, for example. As process gases, 200 sccm or more and 400 sccm or less of Ar, 30 sccm or more and 120 sccm or less of CF₄, and 15 sccm or more and 60 sccm or less of O₂ are supplied to the chamber 31. The pressure in the chamber 31 is 1 Pa or more and 5 Pa or less. The radio-frequency power applied to the antennas 32 is 1500 W or more and 4000 W or less. The radio-frequency power applied to the stage 35 is 150 W or more and 600 W or less. The processing time is 15 seconds or more and 60 seconds or less.

The plasma dicing process may be performed by repeating a protective film deposition step, a protective film removal step, and a substrate etching step a plurality of times. The processing conditions in the protective film deposition step are as described below, for example. As a process gas, 150 sccm or more and 600 sccm or less of C₄F₈ is supplied to the chamber 31. The pressure in the chamber 31 is 8 Pa or more and 16 Pa or less. The radio-frequency power applied to the antennas 32 is 2000 W or more and 8000 W or less. The radio-frequency power applied to the stage 35 is 15 W or more and 80 W or less. The processing time is one second or more and five seconds or less. The processing conditions in the protective film removal step are as described below, for example. As a process gas, 200 sccm or more and 800 sccm or less of SF₆ is supplied to the chamber 31. The pressure in the chamber 31 is 4 Pa or more and 12 Pa or less. The radio-frequency power applied to the antennas 32 is 2000 W or more and 8000 W or less. The radio-frequency power applied to the stage 35 is 150 W or more and 600 W or less. The processing time is one second or more and five seconds or less. The processing conditions in the substrate etching step are as described below, for example. As a process gas, 200 sccm or more and 800 sccm or less of SF₆ is supplied to the chamber 31. The pressure in the chamber 31 is 20 Pa or more and 40 Pa or less. The radio-frequency power applied to the antennas 32 is 2500 W or more and 10000 W or less. The radio-frequency power applied to the stage 35 is 20 W or more and 100 W or less. The processing time is two seconds or more and ten seconds or less. The number of iterations of the protective film deposition step, the protective film removal step, and the substrate etching step is 20 or more and 50 or less, for example.

### Supplementary Notes

The following techniques are disclosed by the foregoing description of the embodiments.

### Technique 1

A manufacturing method for an element chip, including:
a preparation process of preparing a substrate that includes a first principal surface and a second principal surface and includes a first layer that is a semiconductor layer and a second layer that is formed on the first principal surface side of the first layer and contains an insulator, the substrate including a plurality of element regions and a division region defining the element regions;
a flattening process of flattening an upper surface of the second layer by polishing the first principal surface side of the substrate;
a protective layer formation process of forming a protective layer on the flattened upper surface to form a boundary between the second layer and the protective layer;
a laser grooving process of irradiating the division region with laser light from the first principal surface side and removing the protective layer and the second layer in the division region to form a groove in the division region that penetrates through the protective layer and the second layer and reaches the first layer, and depositing, on side walls of the groove, a deposit containing compositions of the protective layer and the second layer removed by the irradiation with the laser light so as to cover at least the boundary;
a deposit removal process of removing the deposit to expose the boundary on the side walls; and
a plasma dicing process of, after the deposit removal process, etching the first layer by exposing the groove to plasma in a state where the second principal surface is supported by a support member, and thereby dividing the substrate into a plurality of element chips including the element regions.

### Technique 2

The manufacturing method for an element chip according to technique 1,
in which the deposit removal process is performed by placing the substrate on a stage of a plasma treatment apparatus to which radio-frequency power can be applied and exposing the substrate to plasma, and includes a first removal step that is performed in a state where first radio-frequency power is applied to the stage, and a second removal step that is performed after the first removal step in a state where second radio-frequency power is applied to the stage, and
the second radio-frequency power is larger than the first radio-frequency power.

### Technique 3

The manufacturing method for an element chip according to technique 2,
in which the first removal step is performed by first plasma that is generated with supply of a first raw material gas containing a fluorocarbon and oxygen,
the second removal step is performed by second plasma that is generated with supply of a second raw material gas containing a fluorocarbon, oxygen, and a rare gas, and
the proportion of the rare gas contained in the second raw material gas is higher than the proportion of the rare gas contained in the first raw material gas.

### Technique 4

The manufacturing method for an element chip according to any one of techniques 1 to 3,
in which the deposit removal process is performed by plasma that is capable of etching the protective layer and the second layer, and
through the deposit removal process, the width of the groove at the boundary is increased.

### Technique 5

The manufacturing method for an element chip according to any one of techniques 1 to 4,
in which the groove formed in the laser grooving process has an inclined shape so as to become narrower toward a bottom surface, and
through the deposit removal process, the inclination angle of the side surfaces of the groove in the boundary becomes smaller.

### Technique 6

The manufacturing method for an element chip according to any one of techniques 1 to 5, in which the protective layer contains a water-soluble resin.

### Technique 7

The manufacturing method for an element chip according to technique 6, further including a protective layer removal process of, after the plasma dicing process, removing the protective layer by bringing the protective layer into contact with a cleaning solution containing water.

### Technique 8

A manufacturing method for a bonded body, including
an element chip preparation process of preparing an element chip;
a second substrate preparation process of preparing a second substrate; and
a bonding process of bonding the element chip to the second substrate,
in which the element chip preparation process includes:
a preparation process of preparing a first substrate that includes a first principal surface and a second principal surface and includes a first layer that is a semiconductor layer and a second layer that is formed on the first principal surface side of the first layer and contains an insulator, the first substrate including a plurality of element regions and a division region defining the element regions;
a flattening process of flattening an upper surface of the second layer by polishing the first principal surface side of the first substrate;
a protective layer formation process of forming a protective layer on the flattened upper surface to form a boundary between the second layer and the protective layer;
a laser grooving process of irradiating the division region with laser light from the first principal surface side and removing the protective layer and the second layer in the division region to form a groove in the division region that penetrates through the protective layer and the second layer and reaches the first layer, and depositing, on side walls of the groove, a deposit containing compositions of the protective layer and the second layer removed by the irradiation with the laser light so as to cover at least the boundary;
a deposit removal process of removing the deposit to expose the boundary on the side walls;
a plasma dicing process of, after the deposit removal process, etching the first layer by exposing the groove to plasma in a state where the second principal surface is supported by a support member, and thereby dividing the first substrate into a plurality of the element chips including the element regions; and
a protective layer removal process of, after the plasma dicing process, removing the protective layer, and
in the bonding process, the first principal surface side of the element chip is brought into areal contact with and bonded to the second substrate.

### Technique 9

The manufacturing method for a bonded body according to technique 8,
in which the deposit removal process is performed by placing the first substrate on a stage of a plasma treatment apparatus to which radio-frequency power can be applied and exposing the first substrate to plasma, and includes a first removal step that is performed in a state where first radio-frequency power is applied to the stage, and a second removal step that is performed after the first removal step in a state where second radio-frequency power is applied to the stage, and
the second radio-frequency power is larger than the first radio-frequency power.

### Technique 10

The manufacturing method for a bonded body according to technique 9,
in which the first removal step is performed by first plasma that is generated with supply of a first raw material gas containing a fluorocarbon and oxygen,
the second removal step is performed by second plasma that is generated with supply of a second raw material gas containing a fluorocarbon, oxygen, and a rare gas, and
the proportion of the rare gas contained in the second raw material gas is higher than the proportion of the rare gas contained in the first raw material gas.

### Technique 11

The manufacturing method for a bonded body according to any one of techniques 8 to 10,
in which the deposit removal process is performed by plasma that is capable of etching the protective layer and the second layer, and
through the deposit removal process, the width of the groove at the boundary is increased.

### Technique 12

The manufacturing method for a bonded body according to any one of techniques 8 to 11,
in which the groove formed in the laser grooving process has an inclined shape so as to become narrower toward a bottom surface, and
through the deposit removal process, the inclination angle of the side surfaces of the groove in the boundary becomes smaller.

### Technique 13

The manufacturing method for a bonded body according to any one of techniques 8 to 12, wherein the protective layer contains a water-soluble resin.

### Technique 14

The manufacturing method for a bonded body according to technique 13, wherein in the protective layer removal process, the protective layer is removed by bringing the protective layer into contact with a cleaning solution containing water.

The present disclosure can be used for a manufacturing method for an element chip and a manufacturing method for a bonded body.

### REFERENCE NUMERALS

1: First substrate
1a: First principal surface
1b: Second principal surface
2: First layer
3: Second layer
3a: Metal electrode
3b: Metal electrode
4: Protective layer
5: Groove
6: Boundary
10: Element chip
20: Support member
30: Plasma treatment apparatus
31: Chamber
32: Antenna
33: First radio-frequency power source
34: Treatment room
35: Stage
36: Second radio-frequency power source
37: Gas inlet
38: Raw material gas source
39: Exhaust outlet
40: Vacuum exhaust part
50: Second substrate
51: Semiconductor layer
52: Wiring layer
52a: Metal electrode
D: Deposit
DA: Division region
EA: Element region
W1, W2: Width of groove
θ1, θ2: Inclination angle of groove side surfaces

What is claimed is:

1. A manufacturing method for an element chip, including:
a preparation process of preparing a substrate that includes a first principal surface and a second principal surface and includes a first layer that is a semiconductor layer and a second layer that is formed on the first principal surface side of the first layer and contains an insulator, the substrate including a plurality of element regions and a division region defining the element regions;
a flattening process of flattening an upper surface of the second layer by polishing the first principal surface side of the substrate;
a protective layer formation process of forming a protective layer on the flattened upper surface to form a boundary between the second layer and the protective layer;
a laser grooving process of irradiating the division region with laser light from the first principal surface side and removing the protective layer and the second layer in the division region to form a groove in the division region that penetrates through the protective layer and the second layer and reaches the first layer, and depositing, on side walls of the groove, a deposit containing compositions of the protective layer and the second layer removed by the irradiation with the laser light so as to cover at least the boundary;
a deposit removal process of removing the deposit to expose the boundary on the side walls; and
a plasma dicing process of, after the deposit removal process, etching the first layer by exposing the groove to plasma in a state where the second principal surface is supported by a support member, and thereby dividing the substrate into a plurality of element chips including the element regions.

2. The manufacturing method for an element chip according to claim 1,
wherein the deposit removal process is performed by placing the substrate on a stage of a plasma treatment apparatus to which radio-frequency power can be applied and exposing the substrate to plasma, and includes a first removal step that is performed in a state where first radio-frequency power is applied to the stage, and a second removal step that is performed after the first removal step in a state where second radio-frequency power is applied to the stage, and
the second radio-frequency power is larger than the first radio-frequency power.

3. The manufacturing method for an element chip according to claim 2,
wherein the first removal step is performed by first plasma that is generated with supply of a first raw material gas containing a fluorocarbon and oxygen,
the second removal step is performed by second plasma that is generated with supply of a second raw material gas containing a fluorocarbon, oxygen, and a rare gas, and
the proportion of the rare gas contained in the second raw material gas is higher than the proportion of the rare gas contained in the first raw material gas.

4. The manufacturing method for an element chip according to claim 1,
wherein the deposit removal process is performed by plasma that is capable of etching the protective layer and the second layer, and
through the deposit removal process, the width of the groove at the boundary is increased.

5. The manufacturing method for an element chip according to claim 1,
wherein the groove formed in the laser grooving process has an inclined shape so as to become narrower toward a bottom surface, and
through the deposit removal process, the inclination angle of the side surfaces of the groove in the boundary becomes smaller.

6. The manufacturing method for an element chip according to claim 1, wherein the protective layer contains a water-soluble resin.

7. The manufacturing method for an element chip according to claim 6, further comprising a protective layer removal process of, after the plasma dicing process, removing the protective layer by bringing the protective layer into contact with a cleaning solution containing water.

8. A manufacturing method for a bonded body, including
an element chip preparation process of preparing an element chip;
a second substrate preparation process of preparing a second substrate; and
a bonding process of bonding the element chip to the second substrate,
wherein the element chip preparation process includes:
a preparation process of preparing a first substrate that includes a first principal surface and a second principal surface and includes a first layer that is a semiconductor layer and a second layer that is formed on the first principal surface side of the first layer and contains an insulator, the first substrate including a plurality of element regions and a division region defining the element regions;
a flattening process of flattening an upper surface of the second layer by polishing the first principal surface side of the first substrate;
a protective layer formation process of forming a protective layer on the flattened upper surface to form a boundary between the second layer and the protective layer;
a laser grooving process of irradiating the division region with laser light from the first principal surface side and removing the protective layer and the second layer in the division region to form a groove in the division region that penetrates through the protective layer and the second layer and reaches the first layer, and depositing, on side walls of the groove, a deposit containing compositions of the protective layer and the second layer removed by the irradiation with the laser light so as to cover at least the boundary;
a deposit removal process of removing the deposit to expose the boundary on the side walls;
a plasma dicing process of, after the deposit removal process, etching the first layer by exposing the groove to plasma in a state where the second principal surface is supported by a support member, and thereby dividing the first substrate into a plurality of the element chips including the element regions; and
a protective layer removal process of, after the plasma dicing process, removing the protective layer, and
in the bonding process, the first principal surface side of the element chip is brought into areal contact with and bonded to the second substrate.

9. The manufacturing method for a bonded body according to claim 8,
wherein the deposit removal process is performed by placing the first substrate on a stage of a plasma treatment apparatus to which radio-frequency power can be applied and exposing the first substrate to plasma, and includes a first removal step that is performed in a state where first radio-frequency power is applied to the stage, and a second removal step that is performed after the first removal step in a state where second radio-frequency power is applied to the stage, and
the second radio-frequency power is larger than the first radio-frequency power.

10. The manufacturing method for a bonded body according to claim 9,
wherein the first removal step is performed by first plasma that is generated with supply of a first raw material gas containing a fluorocarbon and oxygen,
the second removal step is performed by second plasma that is generated with supply of a second raw material gas containing a fluorocarbon, oxygen, and a rare gas, and
the proportion of the rare gas contained in the second raw material gas is higher than the proportion of the rare gas contained in the first raw material gas.

11. The manufacturing method for a bonded body according to claim 8,
wherein the deposit removal process is performed by plasma that is capable of etching the protective layer and the second layer, and
through the deposit removal process, the width of the groove at the boundary is increased.

12. The manufacturing method for a bonded body according to claim 8,
wherein the groove formed in the laser grooving process has an inclined shape so as to become narrower toward a bottom surface, and
through the deposit removal process, the inclination angle of the side surfaces of the groove in the boundary becomes smaller.

13. The manufacturing method for a bonded body according to claim 8, wherein the protective layer contains a water-soluble resin.

14. The manufacturing method for a bonded body according to claim 13, wherein in the protective layer removal process, the protective layer is removed by bringing the protective layer into contact with a cleaning solution containing water.
